(19) United States
(12) Patent Application Publication
(10) Pub. No.: US 2010/0239781 A1
(43) Pub. Date: Sep. 23, 2010

(54) METHOD FOR IN-CHAMBER PREPROCESSING IN PLASMA NITRIDATION PROCESSING, PLASMA PROCESSING METHOD, AND PLASMA PROCESSING APPARATUS

(76) Inventors: Masaki Sano, Yamanashi-ken (JP); Shuuichi Ishizuka, Yamanashi-ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/601,954

(22) PCT Filed: May 27, 2008
(86) PCT No.: PCT/JP2008/059701

§ 371 Date: Jun. 4, 2010

(30) Foreign Application Priority Data
May 29, 2007 (JP) 2007-141423

(51) Int. Cl. C23C 16/44; C23C 16/00

(52) U.S. Cl. 427/569; 118/723 R

(57) ABSTRACT

Disclosed is an in-chamber preprocessing method for carrying out preprocessing in a chamber prior to carrying out plasma nitridation processing of an oxide film, formed on a substrate, in the chamber. The method includes a step of supplying an oxygen-containing processing gas into the chamber and converting the gas into plasma, thereby generating an oxidizing plasma in the chamber (step 1), and a step of supplying a nitrogen-containing processing gas into the chamber and converting the gas into plasma, thereby generating a nitriding plasma in the chamber (step 2).

### TECHNICAL FIELD

The present invention relates to a method for in-chamber preprocessing in plasma nitridation processing, such as nitridation of a gate insulating film, and to a plasma processing method and a plasma processing apparatus.

### BACKGROUND ART

Because of the demand for LSI's higher integration and higher speed, design rules on semiconductor devices are becoming increasingly finer these days. This requires reduction in the EOT (equivalent oxide thickness), i.e. the thickness of an SiO₂ film equivalent in electric capacitance, of a gate insulating film in a CMOS device. Nitridation of an oxide film is effective to reduce the EOT of a gate insulating film; and a single-substrate plasma nitridation processing is known as a method for the nitridation of such an oxide film (e.g. Japanese Patent Laid-Open Publications Nos. 2000-260767 and 2000-294550).

If variation in the nitrogen concentration of a nitrided oxide film is produced in such nitridation processing, the variation will cause variation in the electrical characteristics, such as EOT and Vth shift, of a transistor, resulting in lowering of the production yield of the semiconductor device. There is, therefore, an ever stricter requirement for uniformity of the nitrogen concentration; and small variation is required not only within the surface of a semiconductor wafer, but among wafers as well. Attempts have therefore been made to carry out nitridation processing uniformly within the surface of a semiconductor wafer and among semiconductor wafers by best controlling the conditions of the nitridation processing.

Before carrying out such a single-substrate plasma nitridation processing in a chamber, processing of bare wafer(s) in the chamber is sometimes carried out as a countermeasure against particles and for conditioning in the chamber. When a real wafer (product wafer), having an oxide film, is inserted into the chamber immediately after the processing of the bare wafer, the resultant nitrogen concentration of the nitrided oxide film of the real wafer is considerably high. Further, in cases where after carrying out nitridation processing of an oxide film on wafers, the apparatus is kept in an idle condition, and then nitridation processing is resumed, the nitrogen concentration of a nitrided oxide film of the first wafer is somewhat low.

Thus, at present it is not possible to eliminate variation in the nitrogen concentration among wafers merely by strictly controlling the nitridation processing conditions, such as pressure, temperature, gas flow rate ratio, etc.

### DISCLOSURE OF THE INVENTION

It is an object of the present invention to provide an in-chamber preprocessing method which, in plasma nitridation processing of an oxide film such as a gate oxide film, can reduce variation in the nitrogen concentration of the nitrided oxide film among substrates.

It is another object of the present invention to provide a plasma processing method which includes such preprocessing, and a plasma processing apparatus.

According to a first aspect of the present invention, there is provided an in-chamber preprocessing method for carrying out preprocessing in a chamber prior to carrying out plasma nitridation processing of an oxide film, formed on a substrate, in the chamber, said method comprising: supplying an oxygen-containing processing gas into the chamber and converting the gas into plasma, thereby generating an oxidizing plasma in the chamber; and supplying a nitrogen-containing processing gas into the chamber and converting the gas into plasma, thereby generating a nitriding plasma in the chamber.

In the first aspect, the oxygen-containing processing gas may contain O₂ gas and the nitrogen-containing processing gas may contain N₂ gas. In particular, the oxidizing plasma may be generated by converting the oxygen-containing processing gas, consisting of O₂ gas, N₂ gas and a rare gas, into plasma, and the nitriding plasma may be generated by converting the nitrogen-containing processing gas, consisting of N₂ gas and a rare gas, into plasma. The nitriding plasma may be generated after generating the oxidizing plasma. Preferably, the oxidizing plasma and the nitriding plasma are generated while a dummy substrate is placed on a substrate stage in the chamber. Further, the generation time of the nitriding plasma is preferably longer than the generation time of the oxidizing plasma.

According to a second aspect of the present invention, there is provided a plasma processing method comprising: a preprocessing step comprising supplying an oxygen-containing processing gas into a chamber and converting the gas into plasma, thereby generating an oxidizing plasma in the chamber, and supplying a nitrogen-containing processing gas into the chamber and converting the gas into plasma, thereby generating a nitriding plasma in the chamber; and a subsequent plasma nitridation step comprising placing a substrate to be processed, having an oxide film, on a substrate stage in the chamber, and supplying a nitrogen-containing processing gas into the chamber and converting the gas into plasma, thereby nitriding the oxide film.

In the second aspect, the nitrogen-containing processing gas in the plasma nitridation step may contain N₂ gas.

Further, in the second aspect, the same conditions as described above with reference to the first aspect may be employed in the preprocessing.

According to a third aspect of the present invention, there is provided a plasma processing apparatus comprising: a chamber that houses a substrate to be processed; a processing gas supply mechanism that supplies a processing gas into the chamber; an exhaust mechanism that evacuates the chamber; a plasma generation mechanism that generates a plasma in the chamber; and a control mechanism that controls the apparatus such that it carries out a plasma processing method comprising: a preprocessing step comprising supplying an oxygen-containing processing gas into the chamber and converting the gas into plasma, thereby generating an oxidizing plasma in the chamber, and supplying a nitrogen-containing processing gas into the chamber and converting the gas into plasma, thereby generating a nitriding plasma in the chamber; and a subsequent plasma nitridation step comprising placing a substrate to be processed, having an oxide film, on a substrate stage in the chamber, and supplying a nitrogen-containing processing gas into the chamber and converting the gas into plasma, thereby nitriding the oxide film.

According to a fourth aspect of the present invention, there is provided a storage medium which operates on a computer and in which a program for controlling a plasma processing apparatus is stored, said program, upon its execution, causing the computer to control the plasma processing apparatus such that it carries out an in-chamber preprocessing method for carrying out preprocessing in a chamber prior to carrying out plasma nitridation processing of an oxide film, formed on a substrate, in the chamber, said method comprising: supplying an oxygen-containing processing gas into the chamber and converting the gas into plasma, thereby generating an oxidizing plasma in the chamber; and supplying a nitrogen-containing processing gas into the chamber and converting the gas into plasma, thereby generating a nitriding plasma in the chamber.

According to a fifth aspect of the present invention, there is provided a storage medium which operates on a computer and in which a program for controlling a plasma processing apparatus is stored, said program, upon its execution, causing the computer to control the plasma processing apparatus such that it carries out a plasma processing method comprising: a preprocessing step comprising supplying an oxygen-containing processing gas into a chamber and converting the gas into plasma, thereby generating an oxidizing plasma in the chamber, and supplying a nitrogen-containing processing gas into the chamber and converting the gas into plasma, thereby generating a nitriding plasma in the chamber; and a subsequent plasma nitridation step comprising placing a substrate to be processed, having an oxide film, on a substrate stage in the chamber, and supplying a nitrogen-containing processing gas into the chamber and converting the gas into plasma, thereby nitriding the oxide film.

The present inventors, from studies made to achieve the above objects, have found the following facts: When nitridation processing of an oxide film is carried out repeatedly, oxygen which has been replaced with nitrogen is released in a chamber, and therefore the processing involves some re-oxidation of the film and comes to a steady state in which the nitrogen concentration of the nitrided oxide film is lower as compared to the case of pure nitridation. Such release of oxygen does not occur in processing of a substrate having no oxide film, such as a bare wafer. When the apparatus is kept in an idle condition after carrying out nitridation processing of an oxide film, the nitriding power of the apparatus decreases e.g. due to the influence of residues in the processing container. It has been found that in such cases the atmosphere in the chamber can be stabilized and the atmosphere can be made similar to that during nitridation processing of an oxide film by generating an oxidizing plasma of an oxygen-containing gas in the chamber to adjust the oxygen concentration in the chamber and by further generating a nitriding plasma of a nitrogen-containing gas in the chamber. Such conditioning of the in-chamber atmosphere can reduce variation in the nitrogen concentration of a nitrided oxide film among substrates in subsequent successive nitridation processing of the substrates. The present invention has been made based on the above findings.

According to the present invention, by carrying out the preprocessing, which involves the generation of an oxidizing plasma and the generation of a nitriding plasma in a chamber, prior to plasma nitridation processing of an oxide film, the atmosphere in the chamber can be made similar to that during nitridation processing of the oxide film. This can reduce variation in the nitrogen concentration of the nitrided oxide film among substrates in the subsequent plasma nitridation processing.

The term “oxidizing plasma” herein refers to a plasma having oxidizing power, formed by exciting an oxygen-containing gas, and the term “nitriding plasma” herein refers to a plasma having nitriding power, formed by exciting a nitrogen-containing gas.

### BRIEF DESCRIPTION OF THE DRAWINGS

FIG. 1 is a schematic cross-sectional view of a plasma processing apparatus suited for carrying out a method according to the present invention.

FIG. 2 is a diagram illustrating the structure of a plane antenna member.

FIG. 3 is a diagram illustrating a preprocessing method according to the present invention.

FIG. 4 is a flow chart illustrating a plasma processing process comprising a preprocessing step and a plasma nitridation step.

FIG. 5 is a graph showing change in the N concentration of oxide films formed on respective wafers, relating to conventional technique, in a case where, immediately after a bare silicon wafer was subjected to nitridation processing, wafers each having an oxide film were subjected to nitridation processing; and in a case where, after wafers each having an oxide film were processed and then the apparatus was kept in an idle condition with a vacuum in-chamber atmosphere, wafers each having an oxide film were subjected to nitridation processing.

FIG. 6 is a graph showing change in the N concentration of oxide films formed on respective wafers, relating to embodiments of the present invention, in a case where, after a bare silicon wafer was subjected to nitridation processing, preprocessing with oxidizing plasma and nitriding plasma was carried out, and then wafers each having an oxide film were subjected to nitridation processing; and in a case where, after wafers each having an oxide film were processed and then the apparatus was kept in an idle condition with a vacuum in-chamber atmosphere, preprocessing with oxidizing plasma and nitriding plasma was carried out, and then wafers each having an oxide film were subjected to nitridation processing.

FIG. 7 is a diagram showing variation in the N concentration of oxide films among wafers, relating to conventional technique, in a case where, after wafers each having an oxide film were processed and then the apparatus was then kept in an idle condition with a vacuum in-chamber atmosphere, wafers each having an oxide film were subjected to nitridation processing without preprocessing prior to the nitridation processing; and in a case which differs from the former case in that preprocessing by irradiation of oxidizing plasma for 5, 7 or 9 seconds, followed by irradiation of nitriding plasma was carried out.

FIG. 8 is a graph showing change in the N concentration of oxide films formed on respective wafers after being subjected to nitridation processing, relating to an embodiment of the present invention, in a case where, after a bare silicon wafer was subjected to nitridation processing, preprocessing by irradiation of an oxidizing plasma for 9 seconds, followed by irradiation of a nitriding plasma for 105 seconds was carried out prior to the nitridation processing; and in a case where, after wafers each having an oxide film were processed and then the apparatus was kept in an idle condition with a vacuum in-chamber atmosphere, preprocessing by irradiation of an oxidizing plasma for 9 seconds, followed by irradiation of a nitriding plasma for 105 seconds was carried out prior to the nitridation processing.

### BEST MODE FOR CARRYING OUT THE INVENTION

Preferred embodiments of the present invention will now be described with reference to the drawings.

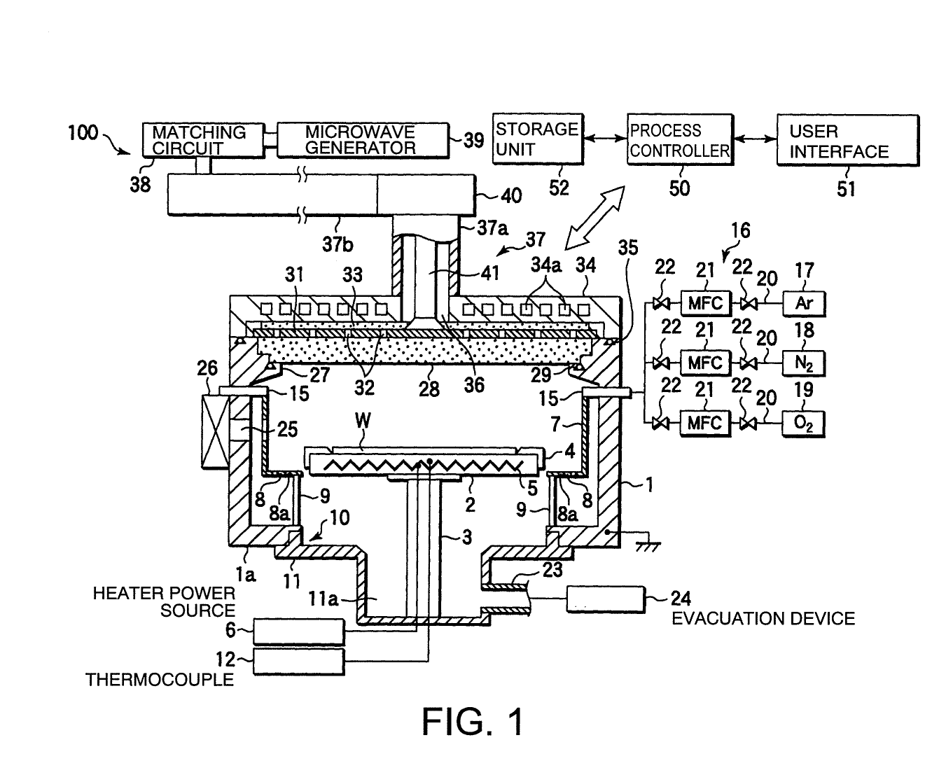

FIG. 1 is a cross-sectional diagram schematically illustrating a plasma processing apparatus suited for carrying out an in-chamber preprocessing method according to the present invention. The plasma processing apparatus is constructed as an RLSA microwave plasma processing apparatus capable of generating a high-density and low-electron temperature microwave plasma by introducing microwaves into a processing chamber by means of an RLSA (radial line slot antenna), which is a plane antenna having a plurality of slots.

The plasma processing apparatus 100 includes a generally-cylindrical airtight and grounded chamber 1. A circular opening 10 is formed generally centrally in the bottom wall 1a of the chamber 1. The bottom wall 1a is provided with a downwardly-projecting exhaust chamber 11 which communicates with the opening 10.

In the chamber 1 is provided a susceptor 2 (stage), made of a ceramic such as AlN, for horizontally supporting a semiconductor wafer (hereinafter referred to simply as “wafer”) W as a substrate to be processed. The susceptor 2 is supported by a cylindrical support member 3, made of a ceramic such as AlN, extending upwardly from the center of the bottom of the exhaust chamber 11. The susceptor 2, in its peripheral portion, is provided with a guide ring 4 for guiding the wafer W. A resistance heating-type heater 5 is embedded in the susceptor 2. The heater 5, when powered from a heater power source 6, heats the susceptor 2 and, by the heat, heats the wafer W as a processing object. The wafer processing temperature can be controlled e.g. in the range of room temperature to 800° C.

The susceptor 2 is provided with wafer support pins (not shown) for raising and lowering the wafer W while supporting it. The wafer support pins are each projectable and retractable with respect to the surface of the susceptor 2.

A cylindrical liner 7 of quarts is provided on the inner circumference of the chamber 1. Further, an annular quartz baffle plate 8, having a large number of exhaust holes 8a for uniformly evacuating the chamber 1, is provided around the circumference of the susceptor 2. The baffle plate 8 is supported on support posts 9.

An annular gas introduction member 15 is provided in the side wall of the chamber 1, and gas radiation holes are formed uniformly in the gas introduction member 15. A gas supply system 16 is connected to the gas introduction member 15. It is also possible to use a gas introduction member having the shape of a shower head. The gas supply system 16 has an Ar gas supply source 17, an N₂ gas supply source 18 and an O₂ gas supply source 19. These gases each pass through a respective gas line 20 and reach the gas introduction member 15, and are uniformly introduced from the gas radiation holes of the gas introduction member 15 into the chamber 1. The gas lines 20 are each provided with a mass flow controller 21 and on-off valves 22 located upstream and downstream of the controller 21.

An exhaust pipe 23 is connected to the side wall of the exhaust chamber 11, and to the exhaust pipe 23 is connected an exhaust device 24 including a high-speed vacuum pump. By the actuation of the exhaust device 24, the gas in the chamber 1 is uniformly discharged into the space 11a of the exhaust chamber 11, and discharged through the exhaust pipe 23 to the outside. The chamber 1 can thus be quickly depressurized into a predetermined vacuum level, e.g. 0.133 Pa.

The side wall of the chamber 1 is provided with a transfer port 25 for transferring the wafer W between the plasma processing apparatus 100 and an adjacent transfer chamber (not shown), and a gate valve 26 for opening and closing the transfer port 25.

The chamber 1 has a top opening, and an annular support 27, projecting inwardly in the chamber 1, is provided along the periphery of the opening. A microwave-transmissive plate 28, which is made of a dielectric material, e.g. a ceramic such as quartz or Al₂O₃ and is transmissive to microwaves, is provided on the support 27. The interface between the plate 28 and the support 27 is hermetically sealed with a seal member 29, so that the chamber 1 is kept hermetic.

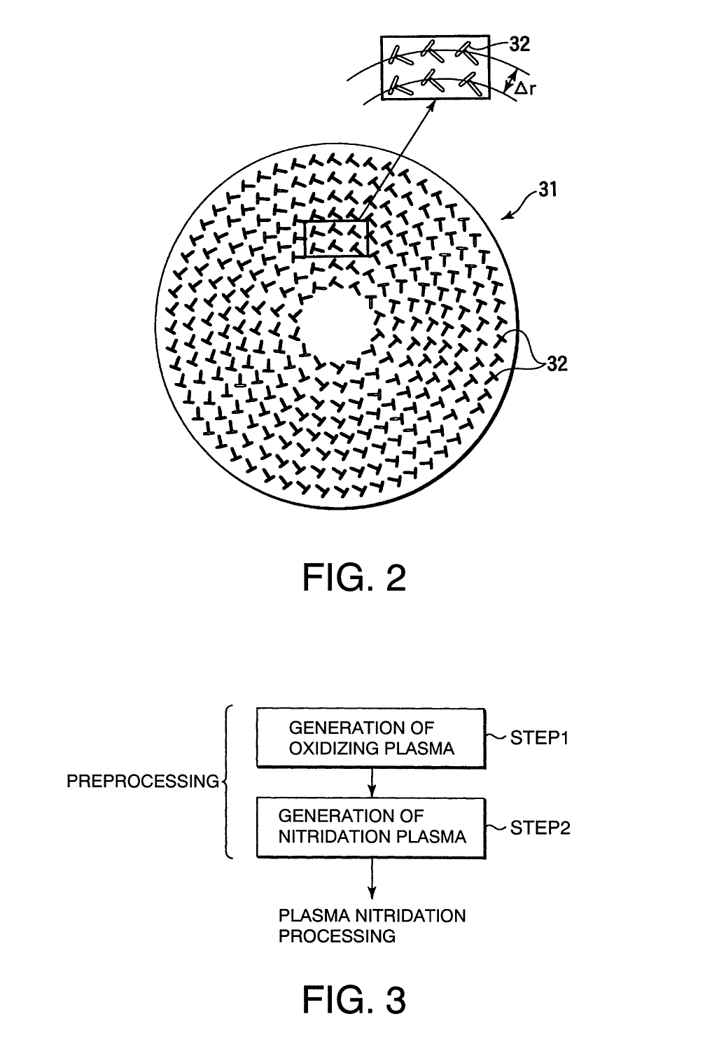

A disk-shaped plane antenna member 31 is provided over the microwave-transmissive plate 28 such that it faces the susceptor 2. The plane antenna member 31 is locked into the upper end of the side wall of the chamber 1. The plane antenna member 31 is a circular plate of conductive material and, when the wafer W is of 8 inch size, has a diameter of 300 to 400 mm and a thickness of 0.1 to a few mm (e.g. 1 mm). For example, the plane antenna member 31 is comprised of a copper or aluminum plate whose surface is plated with silver or gold, and has a large number of microwave radiating holes (slots) 32 penetrating the plane antenna member 31 and formed in a predetermined pattern. As shown in FIG. 2, each microwave radiating hole 32 is a slot-like hole, and adjacent two microwave radiating holes 32 are paired typically in a letter “T” arrangement. The pairs of microwave radiating holes 32 are arranged in concentric circles as a whole. The length of the microwave radiating holes 32 and the spacing in their arrangement are determined depending on the wavelength (λg) of microwaves. For example, the microwave radiating holes 32 are arranged with a spacing of λg/4 to λg. In FIG. 2, the spacing between adjacent concentric lines of microwave radiating holes 32 is denoted by Δr. The microwave radiating holes 32 may have other shapes, such as a circular shape and an arch shape. The arrangement of the microwave radiating holes 32 is not limited to the concentric arrangement: the microwave radiating holes 32 may be arranged e.g. in a spiral or radial arrangement.

A retardation member 33 e.g. made of quartz or a resin such as polytetrafluoroethylene or polyimide, having a higher dielectric constant than vacuum, is provided on the upper surface of the plane antenna member 31. The retardation member 33 is employed in consideration of the fact that the wavelength of microwaves becomes longer in vacuum. The retardation member 33 functions to shorten the wavelength of microwaves, thereby adjusting plasma. The plane antenna member 31 and the microwave-permeable plate 28, and the retardation member 33 and the plane antenna member 31 may be in contact with or spaced apart from each other.

A shield cover 34, made of a metal material such as aluminum, stainless steel or copper, is provided on the upper surface of the chamber 1 such that it covers the plane antenna member 31 and the retardation member 33. The interface between the upper surface of the chamber 1 and the shield cover 34 is sealed with a seal member 35. A cooling water flow passage 34a is formed in the interior of the shield cover 34. The shield cover 34, the retardation member 33, the plane antenna member 31 and the microwave-permeable plate 28 can be cooled by passing cooling water through the cooling water flow passage 34a, thereby preventing their deformation or breakage. The shield cover 34 is grounded.

An opening 36 is formed in the center of the upper wall of the shield cover 34, and a waveguide 37 is connected to the opening 36. The other end of the waveguide 37 is connected via a matching circuit 38 to a microwave generator 39. Thus, microwaves e.g. having a frequency of 2.45 GHz, generated in the microwave generator 39, are transmitted through the waveguide 37 to the plane antenna member 31. Other microwave frequencies such as 8.35 GHz and 1.98 GHz can also be used.

The waveguide 37 is comprised of a coaxial waveguide 37a having a circular cross-section and extending upward from the opening 36 of the shield cover 34, and a horizontally-extending rectangular waveguide 37b connected via a mode converter 40 to the upper end of the coaxial waveguide 37a. The mode converter 40 between the rectangular waveguide 37b and the coaxial waveguide 37a functions to convert microwaves, propagating in TE mode through the rectangular waveguide 37b, into TEM mode. An inner conductor 41 extends centrally in the coaxial waveguide 37a. The lower end of the inner conductor 41 is connected and secured to the center of the plane antenna member 31. Thus, microwaves are propagated through the inner conductor 41 of the coaxial waveguide 37a to the plane antenna member 31 uniformly and efficiently.

The respective components of the plasma processing apparatus 100, such as the heater power source 6, the mass flow controllers 21, the on-off valves 22, the exhaust device 24, the gate valve 26, the microwave generator 39, etc., are connected to and controlled by a process controller 50 provided with a microprocessor (computer). A thermocouple 12 as a temperature sensor is also connected to the process controller 50, so that the process controller 50 controls the heater power source 6 based on a signal from the thermocouple 12.

Connected to the process controller 50 is a user interface 51 which includes a keyboard for an operator to perform a command input operation, etc. in order to manage the plasma processing apparatus 100, a display which visualizes and displays the operating situation of the plasma processing apparatus 100, etc.

Also connected to the process controller 50 is a storage unit 52 in which are stored a control program for executing, under control of the process controller 50, various process steps to be carried out in the plasma processing apparatus 100, and a program, or a processing recipe, for causing the respective components of the plasma processing apparatus 100 to execute their processing in accordance with processing conditions. The processing recipe is stored in a storage medium in the storage unit 52. The storage medium may be a hard disk or a semiconductor memory, or a portable medium such as CD-ROM, DVD, flash memory, etc. It is also possible to transmit the processing recipe from another device e.g. via a dedicated line as needed.

A desired processing in the plasma processing apparatus 100 is carried out under the control of the process controller 50 by calling up an arbitrary processing recipe from the storage unit 52 and causing the process controller 50 to execute the processing recipe, e.g. through the operation of the user interface 51 performed as necessary.

A plasma nitridation processing recipe and a preprocessing recipe are stored in the storage medium of the storage unit 52. The plasma nitriding processing recipe is to carry out plasma nitridation processing of an oxide film formed on the wafer W, and the preprocessing recipe is to control the atmosphere in the chamber 1 in advance of the plasma nitridation processing so as to control the nitrogen concentration of the oxide film after nitridation.

The operation of the plasma processing apparatus 100 thus constructed will now be described. When carrying out plasma nitridation of an oxide film, such as a gate insulating film, in the plasma processing apparatus 100, the gate valve 26 is first opened, and a wafer W is carried from the transfer port 25 into the chamber 1 and placed on the susceptor 2.

Next, Ar gas and N₂ gas are supplied from the Ar gas supply source 17 and the N₂ gas supply source 18 of the gas supply system 16 and introduced through the gas introduction member 15 into the chamber 1 respectively at a predetermined flow rate; and a predetermined processing pressure is maintained. The processing conditions are as follows: The flow rate of the Ar gas is, for example, in the range of 100 to 5000 mL/min (sccm), preferably in the range of 1000 to 3000 mL/min (sccm); and the flow rate of the N₂ gas is, for example, in the range of 10 to 1000 mL/min (sccm), preferably in the range of 10 to 200 mL/min (sccm). The processing pressure in the chamber is, for example, in the range of 6.7 to 266.7 Pa. The processing temperature is, for example, in the range of 100 to 500° C.

Microwaves from the microwave generator 39 are then introduced via the matching circuit 38 into the waveguide 37. The microwaves pass through the rectangular waveguide 37b, the mode converter 40 and the coaxial waveguide 37a, and are supplied to the plane antenna member 31. The microwaves propagate in TE mode in the rectangular waveguide 37b, the TE mode of the microwaves are converted into TEM mode by the mode converter 40 and the TEM mode microwaves are propagated in the coaxial waveguide 37a toward the plane antenna member 31. The microwaves are then radiated from the plane antenna member 31 through the microwave-permeable plate 28 into the space above the wafer W in the chamber 1. The Ar gas and the N₂ gas are converted into plasma by the irradiating microwaves, and an oxide film, such as a gate insulating film, formed on the wafer W is nitrided by the plasma. The power of the microwaves is, for example, 500 to 5000 W, preferably 1000 to 3000 W. The plasma nitridation processing is carried out based on the plasma nitridation processing recipe stored in the storage medium of the storage unit 52.

The microwave plasma thus formed is high-density/low-electron temperature plasma having a density of about 1×10¹⁰ to 5×10¹²/cm³ or even more and an electron temperature of about 0.5 to 2 eV. The plasma therefore enables high-precision nitridation processing with low damage to the underlying material. Such plasma is effective especially for nitridation of a gate insulating film for which low-damage, high-precision nitridation processing is required.

Before carrying out such plasma nitridation processing in a chamber, processing of a bare wafer(s) (a wafer which have not undergone any processing), having no oxide film, in the chamber is sometimes carried out as a countermeasure against particles and for conditioning in the chamber. When a real (product) wafer (substrate), having an oxide film, is inserted into the chamber immediately after the processing of the bare wafer, and nitridation processing of the real wafer and subsequent wafers is carried out successively, the nitrogen concentration of the nitrided oxide film of the first several wafers is considerably high. Further, in cases where after carrying out nitridation processing of oxide films on wafers, the apparatus is kept in an idle condition, and then nitridation processing is resumed, the nitrogen concentration of nitrided oxide films is low in the first few wafers in the resumed processing. In general, after carrying out nitridation processing of an oxide film repeatedly, the processing comes to a steady state [when the nitrogen concentration of a nitrided oxide film becomes substantially constant (the nitrogen concentration falling within the range of product specs) after successive nitridation processing from the first wafer]. Because of the abnormal nitrogen concentrations in the first few wafers, there is a significant variation in the nitrogen concentration of the oxide film between wafers (after nitridation processing).

The following are the reasons for the high nitrogen concentration after processing of a bare wafer(s): In ordinary successive nitridation processing of an oxide film, oxygen in the oxide film is replaced with active nitrogen and released from the film. Because of the presence of the oxygen in the processing space, the nitridation processing involves some re-oxidation of the film and comes to a steady state in which the nitrogen concentration of the nitrided oxide film is lower as compared to the case of pure nitridation. Such release of oxygen does not occur in processing of a bare wafer having no oxide film. Accordingly, when plasma nitridation of an oxide film on wafers is carried out after processing of a bare wafer, the nitrogen concentration of the oxide film in the first few wafers is higher than that in the above steady state. On the other hand, the low nitrogen concentration after keeping the apparatus in an idle condition is due to the fact that the in-chamber atmosphere has not reached a steady-state nitridation processing atmosphere (in which a sufficient amount of radicals and ions are present), and therefore the nitriding power is low.

According to this embodiment, preprocessing to adjust the in-chamber atmosphere to a steady-state nitridation processing atmosphere is carried out prior to nitridation processing of real wafers with appropriate timing, such as before the start of a lot or immediately after processing of bare wafer(s).

In particular, as shown in FIG. 3, an oxidizing plasma of an oxygen-containing processing gas is first generated in the chamber 1 (step 1), thereby adjusting the oxygen concentration in the chamber. Subsequently, a nitriding plasma of a nitrogen-containing processing gas is generated (step 2), thereby stabilizing the atmosphere in the chamber 1 and bringing the atmosphere near to that during nitridation processing of an oxide film (steady-state nitridation processing atmosphere). The generation of the oxidizing plasma in the chamber 1 can lower the nitrogen concentration of a nitrided oxide film in the first few wafers in the subsequent successive nitridation processing, while the generation of the nitriding plasma in the chamber 1 can raise the nitrogen concentration of the nitrided oxide film. By using the two types of plasmas in combination to condition the atmosphere in the chamber, the nitrogen concentration of a nitrided oxide film can be adjusted to that in a steady state. A gas containing O₂ gas can be used as the oxygen-containing processing gas, and a gas containing N₂ gas can be used as the nitrogen-containing processing gas.

The preprocessing will now be described in greater detail.

First, the gate valve 26 is opened, and a dummy wafer is carried from the transfer port 25 into the chamber 1 and placed on the susceptor 2. The use of a dummy wafer is to protect the susceptor 2, and is not essential.

Next, Ar gas, N₂ gas and O₂ gas are supplied from the Ar gas supply source 17, the N₂ gas supply source 18 and the O₂ gas supply source 19 of the gas supply system 16 and introduced through the gas introduction member 15 into the chamber 1 respectively at a predetermined flow rate; and a predetermined processing pressure is maintained. As with the above-described nitridation processing, microwaves from the microwave generator 39 are radiated through the plane antenna member 31 into the space above the wafer W to form an oxidizing plasma. The processing conditions are as follows: The flow rate of the Ar gas is, for example, in the range of 100 to 5000 mL/min (sccm), preferably in the range of 100 to 2000 mL/min (sccm); the flow rate of the N₂ gas is, for example, in the range of 1 to 100 mL/min (sccm), preferably in the range of 1 to 20 mL/min (sccm); and the flow rate of the O₂ gas is, for example, in the range of 10 to 1000 mL/min (sccm), preferably in the range of 10 to 200 mL/min (sccm). The processing pressure in the chamber is, for example, in the range of 6.7 to 266.7 Pa. The processing temperature is, for example, in the range of 100 to 500° C., preferably in the range of 400 to 500° C. The power of the microwaves is, for example, 500 to 3000 W (0.25 to 1.54 W/cm²), preferably 1000 to 3000 W (0.51 to 1.54 W/cm²). By maintaining the oxidizing plasma for a predetermined time, the atmosphere in the chamber 1 can be brought into a predetermined oxygen concentration irrespective of the conditions in the chamber 1 before the preprocessing. The oxidizing plasma retention time may be short, for example, about 1 to 60 seconds, preferably about 5 to 10 seconds. The use of a longer retention time may result in a strong oxygen atmosphere, necessitating a considerably longer nitridation processing time.

Next, the supply of O₂ gas from the O₂ gas supply source 19 is stopped, and Ar gas and N₂ gas from the Ar gas supply source 17 and the N₂ gas supply source 18 are introduced through the gas introduction member 15 into the chamber 1 respectively at a predetermined flow rate; and a predetermined processing pressure is maintained. As with the above-described nitridation processing, microwaves from the microwave generator 39 are radiated through the plane antenna member 31 into the space above the wafer W to form a nitriding plasma. The processing conditions are as follows: The flow rate of the Ar gas is, for example, in the range of 100 to 6000 mL/min (sccm), preferably in the range of 100 to 2000 mL/min (sccm); and the flow rate of the N₂ gas is, for example, in the range of 10 to 1000 mL/min (sccm), preferably in the range of 10 to 200 mL/min (sccm). The processing pressure in the chamber is, for example, in the range of 6.7 to 266.7 Pa. The processing temperature is, for example, in the range of 100 to 500° C., preferably in the range of 400 to 500° C. The power of the microwaves is, for example, 500 to 3000 W (0.25 to 1.54 W/cm²), preferably 1000 to 3000 W (0.51 to 1.54 W/cm²). By maintaining the nitriding plasma for a predetermined time, for example 50 to 600 seconds, preferably 100 to 200 seconds, the atmosphere in the chamber 1 can be stabilized. If the nitriding plasma is maintained for a longer time, the in-chamber atmosphere is likely to become a strong nitrogen atmosphere with a too high nitrogen concentration, and conversely, if the nitriding plasma is maintained for a shorter time, the in-chamber atmosphere is likely to becomes a strong oxygen atmosphere with a too low nitrogen concentration.

By thus generating the oxidizing plasma and the nitriding plasma, the atmosphere in the chamber 1 can be made similar to that during successive nitridation processing of an oxide film.

Therefore, when subsequently carrying out successive nitridation processing of an oxide film, the nitrogen concentration of the nitrided oxide film of the first wafer(s) can be made substantially the same as that during a steady-state nitridation processing irrespective of the conditions in the chamber 1 before the preprocessing (i.e. irrespective of whether processing of bare wafer(s) or idling of the apparatus has been carried out).

The preprocessing is carried out based on a preprocessing condition recipe stored in the storage medium of the storage unit 52. Optimum oxidizing plasma conditions and nitriding plasma conditions, which have previously been determined, are set in the preprocessing condition recipe. After completion of the preprocessing condition recipe, a main nitridation processing condition recipe is started.

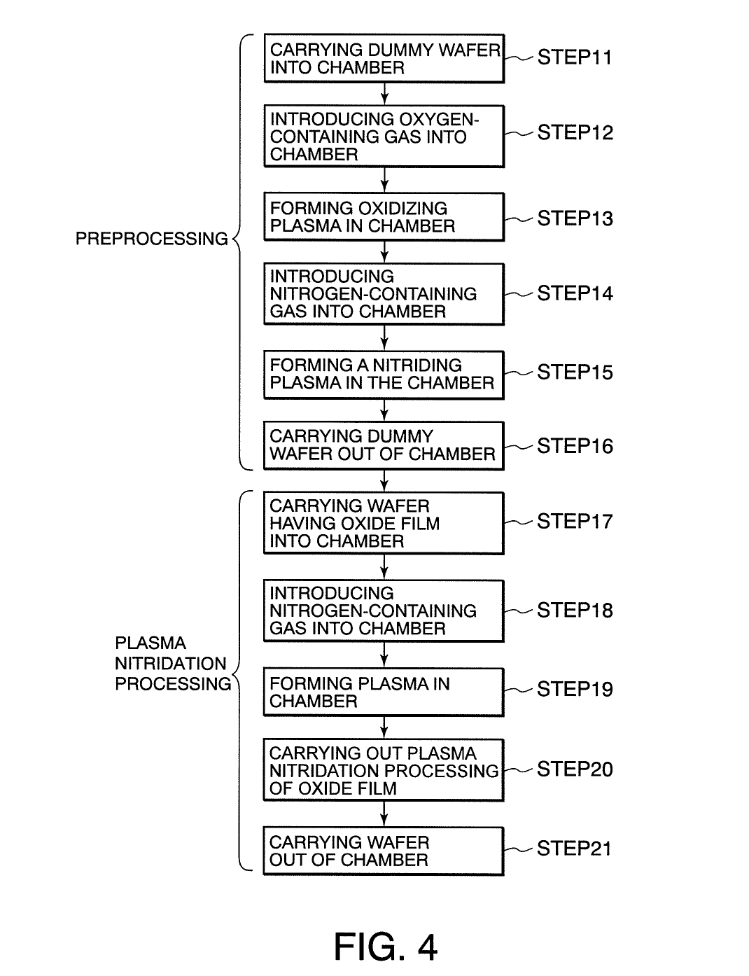

The overall flow of the plasma processing process, comprising the preprocessing and the main nitridation processing, will now be described with reference to the flow chart of FIG. 4.

First, a preprocessing step is carried out.

In the preprocessing step, a dummy wafer is first carried into the chamber 1 and placed on the susceptor 2 (step 11). Next, while evacuating the chamber 1, an oxygen-containing gas, e.g. a mixture of Ar gas, N₂ gas and O₂ gas, is introduced into the chamber 1, thereby bringing the chamber 1 into a predetermined vacuum atmosphere (step 12). Thereafter, microwaves are introduced into the chamber 1 to excite the oxygen-containing gas, thereby forming an oxidizing plasma in the chamber 1 (step 13). An oxygen atmosphere is thus formed in the chamber 1. While the oxygen atmosphere is maintained, extra oxygen is discharged from the chamber 1 by means of the exhaust device 24. Thereafter, while evacuating the chamber 1, a nitrogen-containing gas, e.g. a mixture of Ar gas and N₂ gas, is introduced into the chamber 1 (step 14). In the case where the mixture of Ar gas, N₂ gas and O₂ gas is used for the formation of the oxidizing plasma, an atmosphere containing Ar gas and N₂ gas can be formed merely by stopping the supply of the O₂ gas. Thereafter, microwaves are introduced into the chamber 1 to excite the nitrogen-containing gas, thereby forming a nitriding plasma in the chamber 1 (step 15). A nitrogen atmosphere is thus formed in the chamber 1. While the nitrogen atmosphere is maintained, extra nitrogen is discharged from the chamber 1 by means of the exhaust device 24. After maintaining the nitriding plasma for a predetermined time, the dummy wafer is carried out of the chamber 1 (step 16), thereby completing the preprocessing step.

Next, a plasma nitridation processing step is carried out.

In the plasma nitridation processing step, a wafer (having an oxide film) is first carried into the chamber 1 (step 17). Next, while evacuating the chamber 1, a nitrogen-containing gas, e.g. a mixture of Ar gas and N₂ gas, is introduced into the chamber 1 (step 18). Thereafter, microwaves are introduced into the chamber 1 to excite the nitrogen-containing gas, thereby forming a plasma in the chamber 1 (step 19). Plasma nitridation processing of the oxide film of the wafer is carried out by means of the plasma (step 20). During the plasma nitridation processing, the chamber 1 is continuously evacuated by means of the exhaust device 24. After carrying out the plasma nitridation processing for a predetermined time, the wafer having the nitrided oxide film is carried out of the chamber 1 (step 21), thereby completing the plasma nitridation processing step for the wafer.

A description will now be made of an experiment which was conducted to confirm the technical effects of the present invention.

Using the plasma processing apparatus of FIG. 1, nitridation processing of wafers was carried out in the following conventional manner: Immediately after carrying out successive nitridation processing of 5 bare silicon wafers, 15 wafers having an oxide film (SiO₂) were subjected to successive nitridation processing. For the 1st, 3rd, 5th, 10th and 15th wafers of the 15 wafers, the nitrogen concentration of the nitrided oxide film was measured by XPS (X-ray photoelectron spectroscopy). The nitridation conditions were as follows: pressure in the chamber 20 Pa; gas flow rate Ar/N₂=500/50 (mL/min (sccm)); microwave power 1450 W; temperature 400° C.; and processing time 27 sec. The thickness of the oxide film was 6 nm.

Separately, using the same plasma processing apparatus, successive nitridation processing of wafers, each having the same oxide film as used in the above test, was carried out in the following conventional manner: After carrying out successive nitridation processing of 25 wafers having the oxide film, the apparatus was kept in an idle condition with a vacuum in-chamber atmosphere for 70 hours. Thereafter, 15 wafers having the oxide film were subjected to successive nitridation of the oxide film carried out under the same conditions as in the above test. For the 1st, 3rd, 5th, 10th and 15th wafers of the wafers, the nitrogen (N) concentration of the nitrided oxide film was measured by XPS.

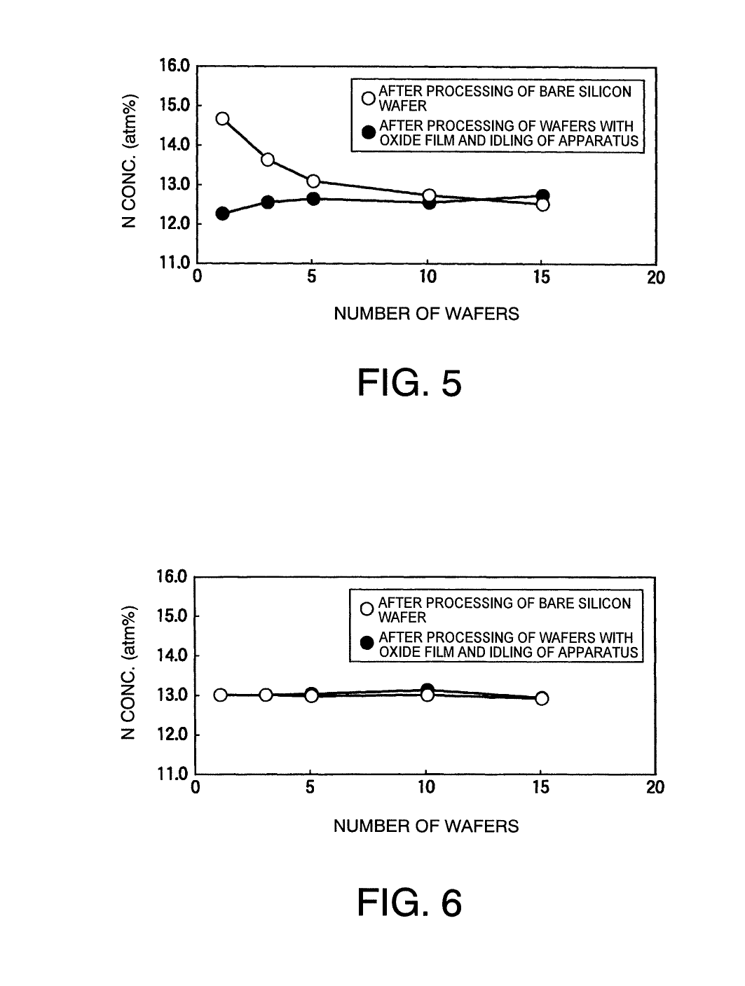

FIG. 5 shows change in the N concentration in the above tests. Further, Table 1 below shows the average N concentration, the range of change in the N concentration and variation in the N concentration. As can be seen from these data, in the successive nitridation processing of wafers carried out after the nitridation processing of bare wafers, the N concentration is considerably high in the first wafer, and decreases with increase in the number of wafers processed. The range of change in the N concentration among wafers was as large as 2.097 atm %. On the other hand, in the successive nitridation processing of wafers carried out after keeping the apparatus in an idle condition, the N concentration is somewhat low in the first wafer and becomes constant after processing of about five wafers. The range of change in the N concentration among wafers (maximum value−minimum value) was 0.494 atm % and the variation in the N concentration among wafers [range/(2× average)] was 1.968%, which values are higher than acceptable values.

TABLE 1

| | | | Variation in N |
|---|---|---|---|
| | | Range of | conc. |
| | Average N | change in N | (range/2 × |
| | conc. | conc. | average) |
| | (atom %) | (atom %) | (%) |
| After idling of | 12.561 | 0.494 | 1.968 |
| apparatus | | | |
| After processing of | 13.348 | 2.097 | 7.855 |
| bare wafers | | | |
| Total | 12.954 | 2.395 | 9.246 |

Next, After carrying out successive nitridation processing of 5 bare wafers and before carrying out successive nitridation processing of 15 wafers, having the oxide film, in the above-described manner and, separately, after carrying out successive nitridation processing of 25 wafers, having the oxide film, in the above-described manner and then keeping the apparatus in an idle condition with a vacuum in-chamber atmosphere for 70 hours and before carrying out successive nitridation processing of 15 wafers, having the oxide film, in the above-described manner, preprocessing was carried out by irradiation of an oxidizing plasma of an oxygen-containing gas for 5 seconds, followed by irradiation of a nitriding plasma of a nitrogen-containing gas for 135 seconds. In the preprocessing, a bare silicon wafer as a dummy wafer was placed on the susceptor to prevent damage to the susceptor. The preprocessing conditions were as follows: pressure in the chamber 20 Pa; microwave power 1450 W; temperature 400° C.; and gas flow rate Ar/N₂/O₂=500/50/50 (mL/min (sccm)) in the generation of the oxidizing plasma, and gas flow rate Ar/N₂=500/50 (mL/min (sccm)) in the generation of the nitriding plasma. For the 1st, 3rd, 5th, 10th and 15th wafers of the 15 wafers which had undergone the nitridation processing carried out under the above-described conditions after the preprocessing, the nitrogen (N) concentration of the nitrided oxide film was measured by XPS. In the preprocessing, the oxidizing plasma may be generated only with the use of Ar gas and O₂ gas without using N₂ gas. The nitriding plasma generation conditions may be the same as the nitridation processing conditions.

FIG. 6 shows change in the N concentration in the above tests. Further, Table 2 below shows the average N concentration, the range of change in the N concentration and variation in the N concentration. As can be seen from these data, both in the successive nitridation processing of wafers carried out after the nitridation processing of bare wafers and in the successive nitridation processing of wafers carried out after keeping the apparatus in an idle condition, the N concentration is constant among wafers. In both cases, the range of change in the N concentration among wafers was as small as less than 0.2 atm % and the variation in the N concentration among wafers was as small as less than 1%. The test results thus demonstrate the effectiveness of the preprocessing with the oxidizing plasma and the nitriding plasma.

TABLE 2

| | | | Variation in N |
|---|---|---|---|
| | | Range of | conc. |
| | Average N | change in N | (range/2 × |
| | conc. | conc. | average) |
| | (atom %) | (atom %) | (%) |
| After idling of | 13.007 | 0.165 | 0.633 |
| apparatus | | | |
| After processing of | 12.950 | 0.119 | 0.461 |
| bare wafers | | | |
| Total | 12.979 | 0.209 | 0.806 |

A description will now be made of an experiment in which preprocessing is carried out under varying conditions in order to determine the optimal conditions.

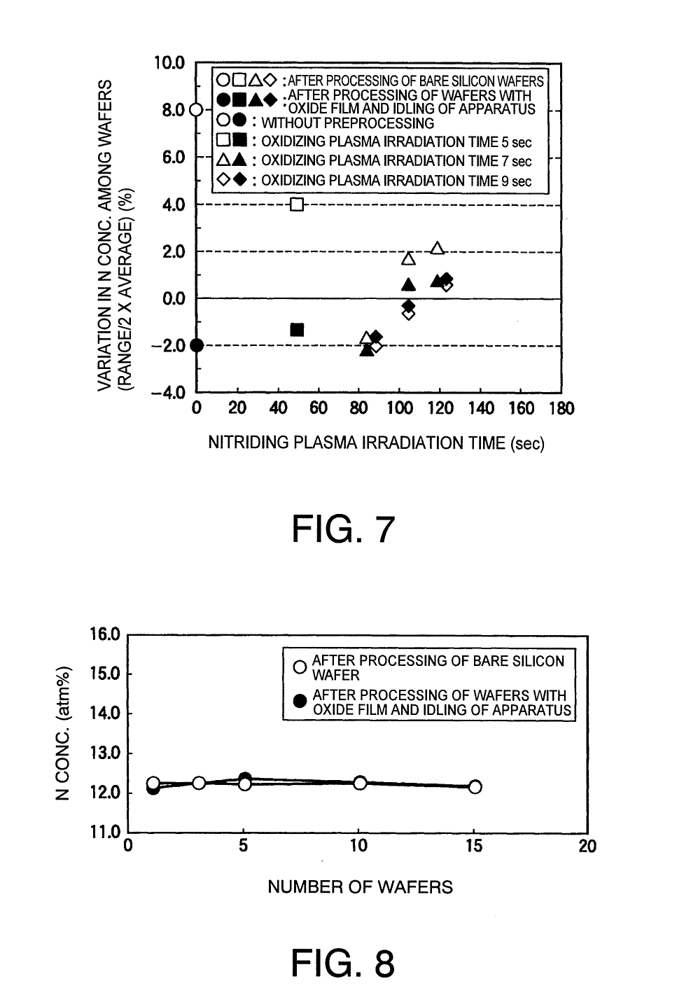

After carrying out successive nitridation processing of 5 bare wafers and before carrying out successive nitridation processing of 15 wafers, having the oxide film, in the above-described manner and, separately, after carrying out successive nitridation processing of 25 wafers, having the oxide film, in the above-described manner and then keeping the apparatus in an idle condition with a vacuum in-chamber atmosphere for 70 hours and before carrying out the successive nitridation processing of 15 wafers, having the oxide film, in the above-described manner, either preprocessing was carried out under the below-described varying conditions or no preprocessing was carried out. The plasma conditions in the respective nitridation processing of 15 wafers were as follows: pressure in the chamber 20 Pa; gas flow rate Ar/N₂=500/50 (mL/min (sccm)); microwave power 1450 W; temperature 400° C.; and processing time 27 sec. For the 1st, 3rd, 5th, 10th and 15th wafers of the 15 wafers, the nitrogen concentration of the nitrided oxide film was measured by XPS, and variation in the nitrogen concentration [the range of change in the nitrogen concentration/(2× average nitrogen concentration)] was determined. In this experiment the target value of the nitrogen concentration was set at 13 atm %. The results are shown in FIG. 7 in which the abscissa represents time for nitridation with a nitriding plasma in the preprocessing and the ordinate represents variation in the nitrogen concentration among wafers. FIG. 7 shows the results in the cases: where no preprocessing was carried out; and where preprocessing was carried out by irradiation of an oxidizing plasma for 5, 7 or 9 seconds, followed by irradiation of a nitriding plasma. The preprocessing conditions were as follows: pressure in the chamber 20 Pa; microwave power 1450 W; temperature 400° C., and gas flow rate Ar/N₂/O₂=500/50/10 (mL/min (sccm)) in the generation of the oxidizing plasma, and gas flow rate Ar/N₂=500/50 (mL/min (sccm)) in the generation of the nitriding plasma. In the preprocessing, a bare silicon wafer, for which nitridation processing had been repeated over 50 times, was used as a dummy wafer.

The data in FIG. 7 indicates that within the scope of this experiment variation in the nitrogen concentration between wafers is smallest when the preprocessing is carried by irradiation of the oxidizing plasma for 9 seconds, followed by irradiation of the nitriding plasma for 105 seconds. FIG. 8 shows change in the nitrogen concentration when the pretreatment is carried out under the optimal conditions. As shown in the Figure, the change in the nitrogen concentration is very small. In particular, the variation in the nitrogen concentration among wafers after processing of bare silicon wafers [the range of change in the nitrogen concentration/(2× average)] is as small as 0.31%.

The allowable range for variation in the nitrogen concentration is at most ±2%. To meet this requirement, preprocessing may preferably be carried out under the following conditions: N₂/O₂ is in the range of 0.5 to 10, preferably in the range of 1 to 5; the oxidizing plasma processing time is in the range of 3 to 120 seconds, preferably in the range of 5 to 120 seconds; and the nitriding plasma processing time is in the range of 50 to 300 seconds. The nitriding plasma processing time is preferably longer than the oxidizing plasma processing time. The variation in the nitrogen concentration is preferably in the range of ±1%. To meet this requirement, preprocessing may preferably be carried out under the following conditions: N₂/O₂ is in the range of 0.5 to 10, preferably in the range of 1 to 5; the oxidizing plasma processing time is in the range of 5 to 10 seconds, preferably in the range of 7 to 10 seconds; and the nitriding plasma processing time is in the range of 90 to 150 seconds, preferably 90 to 120 seconds. The optimal preprocessing conditions vary depending on the thickness of an oxide film, the nitridation processing conditions, etc. It is therefore preferred to prepare a preprocessing recipe in advance based on optimization of the preprocessing conditions according to such factors. Though in the above experiment the target nitrogen concentration is set at 13 atm %, the same technical effect can be achieved with the nitrogen concentration at least in the range of 5 to 30 atm %.

The present invention is not limited to the embodiments described above, but various modifications may be made thereto. For example, though in the embodiments the RLSA-type plasma processing apparatus is used as an apparatus for carrying out the method of the present invention, the present invention is not limited to the use of the apparatus. However, plasma processing apparatuses having a plasma source that employs an antenna, such as apparatuses of the RLSA type or the inductively-coupled plasma (ICP) type, can be most effectively used in the present invention. Examples of other types of plasma processing apparatuses usable in the present invention include remote plasma type, ECR plasma type, surface reflected wave plasma type, magnetron plasma type, etc.

While plasma nitridation processing of a gate insulating film has been described in the above embodiments, the present invention is also applicable to nitridation processing of other insulating films, such as a dielectric film between a control gate and a floating gate in a flash memory. Further, the present invention is not limited to nitridation of a silicon oxide film, but is applicable also to other types of oxide films, for example, a highly dielectric oxide film such as a hafnium oxide film or a hafnium silicate film.

Instead of O₂ gas used for the formation of an oxidizing plasma in the embodiments, it is possible to use other oxygen-containing gases, such as N₂O, NO, NO₂, etc. Further, instead of N₂ gas used for the formation of a nitriding plasma, it is possible to use other nitrogen-containing gases, such as NH₃, MMH, etc.

### INDUSTRIAL APPLICABILITY

The present invention can be advantageously used for nitridation processing of an oxide film, such as a gate insulating film, in the manufacturing of a variety of semiconductor devices.

1. An in-chamber preprocessing method for carrying out preprocessing in a chamber prior to carrying out plasma nitridation processing of an oxide film, formed on a substrate, in the chamber, said method comprising:
supplying an oxygen-containing processing gas into the chamber and converting the gas into plasma, thereby generating an oxidizing plasma in the chamber; and
supplying a nitrogen-containing processing gas into the chamber and converting the gas into plasma, thereby generating a nitriding plasma in the chamber.

2. The in-chamber preprocessing method according to claim 1, wherein the oxygen-containing processing gas contains O₂ gas and the nitrogen-containing processing gas contains N₂ gas.

3. The in-chamber preprocessing method according to claim 1, wherein the oxidizing plasma is generated by converting the oxygen-containing processing gas, consisting of O₂ gas, N₂ gas and a rare gas, into plasma, and the nitriding plasma is generated by converting the nitrogen-containing processing gas, consisting of N₂ gas and a rare gas, into plasma.

4. The in-chamber preprocessing method according to claim 1, wherein the nitriding plasma is generated after generating the oxidizing plasma.

5. The in-chamber preprocessing method according to claim 1, wherein the oxidizing plasma and the nitriding plasma are generated while a dummy substrate is placed on a substrate stage in the chamber.

6. The in-chamber preprocessing method according to claim 1, wherein a generating time of the nitriding plasma is longer than a generating time of the oxidizing plasma.

7. A plasma processing method comprising:
a preprocessing step comprising supplying an oxygen-containing processing gas into a chamber and converting the gas into plasma, thereby generating an oxidizing plasma in the chamber, and supplying a nitrogen-containing processing gas into the chamber and converting the gas into plasma, thereby generating a nitriding plasma in the chamber; and
a subsequent plasma nitridation step comprising placing a substrate to be processed, having an oxide film, on a substrate stage in the chamber, and supplying a nitrogen-containing processing gas into the chamber and converting the gas into plasma, thereby nitriding the oxide film.

8. The plasma processing method according to claim 7, wherein in the preprocessing step, the oxygen-containing processing gas contains O₂ gas and the nitrogen-containing processing gas contains N₂ gas.

9. The plasma processing method according to claim 7, wherein in the preprocessing step, the oxidizing plasma is generated by converting the oxygen-containing processing gas, consisting of O₂ gas, N₂ gas and a rare gas, into plasma, and the nitriding plasma is generated by converting the nitrogen-containing processing gas, consisting of N₂ gas and a rare gas, into plasma.

10. The plasma processing method according to claim 7, wherein in the preprocessing step, the nitriding plasma is generated after generating the oxidizing plasma.

11. The plasma processing method according to claim 7, wherein in the plasma nitridation step, the nitrogen-containing processing gas contains N₂ gas.

12. The plasma processing method according to claim 7, wherein in the preprocessing step, the oxidizing plasma and the nitriding plasma are generated while a dummy substrate is placed on a substrate stage in the chamber.

13. The plasma processing method according to claim 7, wherein in the preprocessing step, a generating time of the nitriding plasma is longer than a generating time of the oxidizing plasma.

14. A plasma processing apparatus comprising:
a chamber that houses a substrate to be processed;
a processing gas supply mechanism that supplies a processing gas into the chamber;
an exhaust mechanism that evacuates the chamber;
a plasma generation mechanism that generates a plasma in the chamber; and
a control mechanism that controls the apparatus such that it carries out a plasma processing method comprising: a preprocessing step comprising supplying an oxygen-containing processing gas into the chamber and converting the gas into plasma, thereby generating an oxidizing plasma in the chamber, and supplying a nitrogen-containing processing gas into the chamber and converting the gas into plasma, thereby generating a nitriding plasma in the chamber; and a subsequent plasma nitridation step comprising placing a substrate to be processed, having an oxide film, on a substrate stage in the chamber, and supplying a nitrogen-containing processing gas into the chamber and converting the gas into plasma, thereby nitriding the oxide film.

15. A storage medium which operates on a computer and in which a program for controlling a plasma processing apparatus is stored, said program, upon its execution, causing the computer to control the plasma processing apparatus such that it carries out an in-chamber preprocessing method for carrying out preprocessing in a chamber prior to carrying out plasma nitridation processing of an oxide film, formed on a substrate, in the chamber, said method comprising: supplying an oxygen-containing processing gas into the chamber and converting the gas into plasma, thereby generating an oxidizing plasma in the chamber; and supplying a nitrogen-containing processing gas into the chamber and converting the gas into plasma, thereby generating a nitriding plasma in the chamber.

16. A storage medium which operates on a computer and in which a program for controlling a plasma processing apparatus is stored, said program, upon its execution, causing the computer to control the plasma processing apparatus such that it carries out a plasma processing method comprising: a preprocessing step comprising supplying an oxygen-containing processing gas into a chamber and converting the gas into plasma, thereby generating an oxidizing plasma in the chamber, and supplying a nitrogen-containing processing gas into the chamber and converting the gas into plasma, thereby generating a nitriding plasma in the chamber; and a subsequent plasma nitridation step comprising placing a substrate to be processed, having an oxide film, on a substrate stage in the chamber, and supplying a nitrogen-containing processing gas into the chamber and converting the gas into plasma, thereby nitriding the oxide film.
